(19) United States
(12) Patent Application Publication
(10) Pub. No.: US 2015/0171808 A1
(43) Pub. Date: Jun. 18, 2015

(54) SMALL SIGNAL AMPLIFIER CIRCUIT

(71) Applicant: SAMSUNG ELECTRO-MECHANICS CO., LTD., Suwon-Si (KR)

(72) Inventor: Tae Ho LIM, Suwon-Si (KR)

(73) Assignee: SAMSUNG ELECTRO-MECHANICS CO., LTD., Suwon-Si (KR)

(21) Appl. No.: 14/244,564

(22) Filed: Apr. 3, 2014

(30) Foreign Application Priority Data
Dec. 16, 2013 (KR) 10-2013-0156606

(51) Int. Cl. H03F 3/45

(52) U.S. Cl. CPC H03F 3/45179; H03F 3/45273; H03F 2203/45051; H03F 2203/45166

(57) ABSTRACT

A signal amplifier circuit may include a bias circuit unit generating a first bias voltage, a level shifting circuit unit shifting a level of an input alternating current (AC) signal by an amount equal to a predetermined direct current (DC) shifting voltage so as to provide a first signal, and a first amplification unit amplifying a difference signal between the first bias voltage and the first signal, the first bias voltage and the DC shifting voltage being generated by circuits having the same characteristics.

### CROSS-REFERENCE TO RELATED APPLICATION

This application claims the benefit of Korean Patent Application No. 10-2013-0156606 filed on Dec. 16, 2013, with the Korean Intellectual Property Office, the disclosure of which is incorporated herein by reference.

### BACKGROUND

The present disclosure relates to a small signal amplifier circuit that amplifies an Alternating Current (AC) signal.

In general, current output from a sensor or the like is converted into voltage via a resistor. Since such voltage is a weak signal that swings around the ground level, it has to be amplified to a level of voltage required by a signal processing unit.

Although it is possible to increase the voltage by increasing resistance of the resistor, it results in thermal noise and loss in power consumption. Therefore, an amplifier is required that amplifies a signal without loss in power.

Typically, in an IC for driving a motor, a series of small resistors is connected along a ground path of a bridge transistor to sense current and convert it into voltage. The voltage is converted into a digital value again by an A/D converter.

The information thus converted may be used for detecting an initial position of a rotor or driving it. Here again, the level of the voltage is small enough for an amplifier with a large gain to be required.

A small signal around the ground level small enough that it may be clipped during amplification. Therefore, for more stable amplification, a fully differential amplifier has frequently been used for amplifying a small signal.

Although such a fully differential amplifier has the advantage of stably amplifying a signal, it has poor efficiency and is more disadvantages.

For examples, a fully differential amplifier is more complicated in terms of design and has a larger size and greater current consumption than a single amplifier. Further, it essentially requires a common mode feedback circuit, which makes the amplifier circuit complicated and increase current consumption.

### SUMMARY

An aspect of the present disclosure may provide a small signal amplification circuit employing a level shifting structure and a single amplification circuit.

According to an aspect of the present disclosure, a small signal amplifier circuit may include: a bias circuit unit configured to generate a first bias voltage; a level shifting circuit unit configured to shift a level of an input alternating current (AC) signal by an amount equal to a predetermined direct current (DC) shifting voltage so as to provide a first signal; and a first amplification unit configured to amplify a difference signal between the first bias voltage and the first signal, the first bias voltage and the DC shifting voltage being generated by circuits having the same characteristics.

According to another aspect of the present disclosure, a small signal amplifier circuit may include: a bias circuit unit generating a first bias voltage; a level shifting circuit unit shifting a level of an input alternating current (AC) signal by an amount equal to a predetermined direct current (DC) shifting voltage so as to provide a first signal; a first amplification unit amplifying a difference signal between the first bias voltage and the first signal so as to provide a second signal; and a second amplification unit amplifying a difference signal between the first bias voltage and the second signal so as to provide a third signal, the first bias voltage and the DC shifting voltage being generated by circuits having the same characteristics.

The bias circuit unit may include: a current source circuit including a main PMOS transistor having a source terminal connected to a terminal of supply voltage and gate and drain terminals connected to each other, and a current source connected between the drain terminal of the main PMOS transistor and ground; and a first bias generation unit including a first PMOS transistor forming a current mirror together with the main PMOS transistor, and a second PMOS transistor having a source terminal connected to the drain of the first PMOS transistor and gate and drain terminals connected to ground, wherein the first bias voltage is provided at a connection node between the first PMOS transistor and the second PMOS transistor.

The level shifting circuit unit may include: a first PMOS transistor forming a current mirror together with the bias circuit unit; and a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

The first amplification unit may include a first operational amplifier having a non-inverting input terminal in which the first bias voltage is received, an inverting input terminal in which the first signal is received via a first resistor, and an output terminal connected to the inverting input terminal via a second resistor, wherein the first operational amplifier inverts and amplifies a difference signal obtained by subtracting the first bias voltage from the first signal by a gain determined according to a ratio of resistance between the first and second resistors so as to provide the second signal.

The second amplification unit may include a second operational amplifier having a non-inverting input terminal in which the first bias voltage is received, an inverting input terminal in which the second signal is received via a third resistor, and an output terminal connected to the inverting input terminal via a fourth resistor, wherein the second operational amplifier inverts and amplifies a difference signal obtained by subtracting the first bias voltage from the second signal by a gain determined according to a ratio of resistance between the third and fourth resistors.

According to another aspect of the present disclosure, a small signal amplifier circuit may include: a bias circuit unit generating a first bias voltage and a second bias voltage different from the first bias voltage; a level shifting circuit unit shifting a level of an input alternating current (AC) signal by an amount equal to a predetermined direct current (DC) shifting voltage so as to provide a first signal; a first amplification unit amplifying a difference signal between the first bias voltage and the first signal so as to provide a second signal; and a second amplification unit amplifying a difference signal between the second bias voltage and the second signal so as to provide a third signal, the first bias voltage and the DC shifting voltage being generated by circuits having the same characteristics.

The bias circuit unit may include: a current source circuit including a main PMOS having a source terminal connected to a terminal of supply voltage and gate and drain terminals connected to each other, and a current source connected between the drain terminal of the main PMOS transistor and ground; a first bias generation unit including a first PMOS transistor forming a current mirror together with the main PMOS transistor, and a second PMOS transistor having a source terminal connected to the drain of the first PMOS transistor and gate and drain terminals connected to ground, wherein the first bias generation unit provides the first bias voltage at a connection node between the first PMOS transistor and the second PMOS transistor; and a second bias generation unit including a third PMOS transistor forming a current mirror together with the main PMOS transistor, and a fourth PMOS transistor having a source terminal connected to the drain of the third PMOS transistor and gate and drain terminals connected to ground, wherein the second bias generation unit provides the second bias voltage at a connection node between the third PMOS transistor and the fourth PMOS transistor.

The level shifting circuit unit may include: a first PMOS transistor forming a current mirror together with the bias circuit unit; and a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

The first amplification unit may include a first operational amplifier having a non-inverting input terminal in which the first bias voltage is received, an inverting input terminal in which the first signal is received via a first resistor, and an output terminal connected to the inverting input terminal via a second resistor, wherein the first operational amplifier inverts and amplifies a difference signal obtained by subtracting the first bias voltage from the first signal by a gain determined according to a ratio of resistance between the first and second resistors so as to provide the second signal.

The second amplification unit may include a second operational amplifier having a non-inverting input terminal in which the second bias voltage is received, an inverting input terminal in which the second signal is received via a third resistor, and an output terminal connected to the inverting input terminal via a fourth resistor, wherein the second operational amplifier inverts and amplifies a difference signal obtained by subtracting the first bias voltage from the second signal by a gain determined according to a ratio of resistance between the third and fourth resistors.

According to another aspect of the present disclosure, a small signal amplifier circuit may include: a current source circuit configured to generate electric current; a first bias circuit unit forming a current mirror together with the current source circuit so as to generate a first bias voltage according to the electric current generated by the current source circuit; a second bias circuit unit forming a current mirror together with the current source circuit so as to generate a second bias voltage according to the electric current generated by the current source circuit, the second bias voltage being higher than the first bias voltage; a level shifting circuit unit configured to shift a level of an input AC signal by an amount equal to a predetermined DC shifting voltage so as to provide a first signal; a first amplification unit configured to amplify a difference signal between the first bias voltage and the first signal so as to provide a second signal; and a second amplification unit configured to amplify a difference signal between the second bias voltage and the second signal so as to provide a third signal, the first bias voltage and the DC shifting voltage being generated by transistor circuits having the same characteristics.

The current source circuit may include: a main PMOS transistor having a source terminal connected to a terminal of supply voltage and gate and drain terminals connected to each other; and a current source connected between the drain terminal of the main PMOS transistor and ground.

The first bias generation unit may include: a first PMOS transistor forming a current mirror together with the main PMOS transistor, and a second PMOS transistor having a source terminal connected to the drain of the first PMOS transistor and gate and drain terminals connected to ground, wherein the first bias voltage is provided at a connection node between the first PMOS transistor and the second PMOS transistor.

The second bias generation unit may include: a third PMOS transistor forming a current mirror together with the main PMOS transistor, and a fourth PMOS transistor having a source terminal connected to the drain of the third PMOS transistor and gate and drain terminals connected to ground, wherein the second bias voltage is provided at a connection node between the third PMOS transistor and the fourth PMOS transistor.

The level shifting circuit unit may include: a first PMOS transistor forming a current mirror together with the bias circuit unit; and a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

The first amplification unit may include a first operational amplifier having a non-inverting input terminal in which the first bias voltage is received, an inverting input terminal in which the first signal is received via a first resistor, and an output terminal connected to the inverting input terminal via a second resistor, wherein the first operational amplifier inverts and amplifies a difference signal obtained by subtracting the first bias voltage from the first signal by a gain determined according to a ratio of resistance between the first and second resistors so as to provide the second signal.

The second amplification unit may include a second operational amplifier having a non-inverting input terminal in which the second bias voltage is received, an inverting input terminal in which the second signal is received via a third resistor, and an output terminal connected to the inverting input terminal via a fourth resistor, wherein the second operational amplifier inverts and amplifies a difference signal obtained by subtracting the first bias voltage from the second signal by a gain determined according to a ratio of resistance between the third and fourth resistors.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram of a small signal amplifier circuit according to an exemplary embodiment of the present disclosure;

FIG. 2 is a block diagram of a small signal amplifier circuit according to another exemplary embodiment of the present disclosure;

FIG. 3 is a block diagram of a small signal amplifier circuit according to another exemplary embodiment of the present disclosure;

FIG. 4 is a block diagram of a bias circuit unit and a level shifting circuit unit according to an exemplary embodiment of the present disclosure;

FIG. 5 is a block diagram of a bias circuit unit and a level shifting circuit unit according to another exemplary embodiment of the present disclosure;

FIG. 6 is a diagram of a first amplification unit according to an exemplary embodiment of the present disclosure;

FIG. 7 is a diagram of a first amplification unit and a second amplification unit according to an exemplary embodiment of the present disclosure; and

FIG. 8 is a set of graphs showing waveforms of an input signal, a first signal, and a second signal.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

FIG. 1 is a block diagram of a small signal amplifier circuit according to an exemplary embodiment of the present disclosure. Referring to FIG. 1, the small signal amplifier circuit according to the exemplary embodiment of the present disclosure may include a bias circuit unit 100, a level shifting circuit unit 200, and a first amplification unit 310.

The bias circuit unit 100 may generate a first bias voltage V_{bias1} to provide it to the first amplification unit 310.

The level shifting circuit unit 200 may shift the level of an input AC signal Vin by an amount equal to a predetermined DC shifting voltage V_{shift} to provide a first signal V1.

The first bias voltage V_{bias1} and the DC shifting voltage V_{shift} may be generated in circuits having the identical characteristic, and, if so, the first bias voltage V_{bias1} and the DC shifting voltage V_{shift} may be almost the identical DC voltage.

The first amplification unit 310 may amplify a difference signal between the first bias voltage V_{bias1} and the first signal V1.

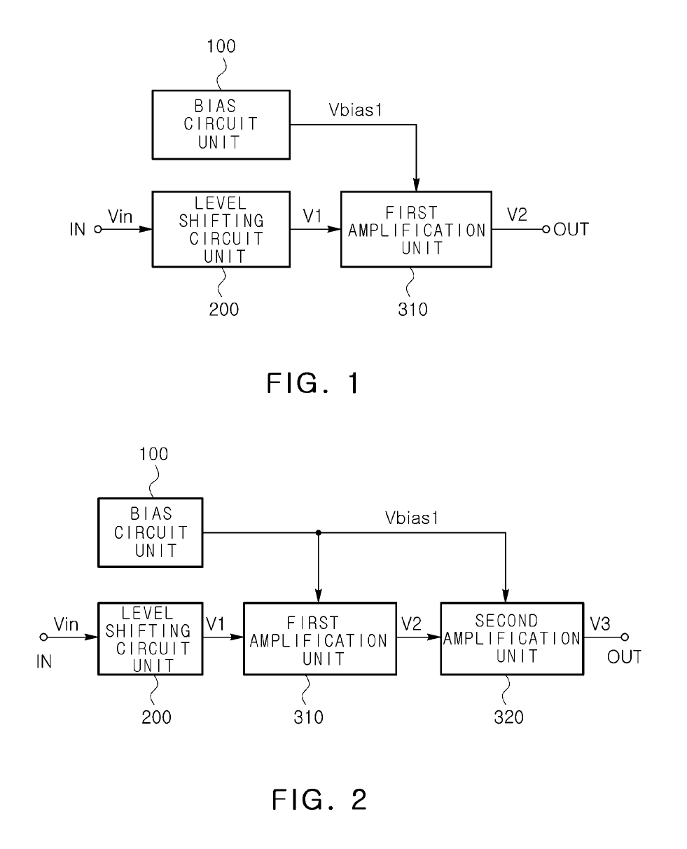

FIG. 2 is a block diagram of a small signal amplifier circuit according to another exemplary embodiment of the present disclosure.

Referring to FIG. 2, the small signal amplifier circuit according to this exemplary embodiment of the present disclosure may include a bias circuit unit 100, a level shifting circuit unit 200, a first amplification unit 310, and a second amplification unit 320.

The operations of the bias circuit unit 100, the level shifting circuit unit 200, and the first amplification unit 310 shown in FIG. 2 are identical to those described above with respect to FIG. 1 and, therefore, redundant descriptions will not be made.

Referring to FIG. 2, the second amplification unit 320 may amplify a difference signal between the first bias voltage V_{bias1} and the second signal V2 so as to provide a third signal V3.

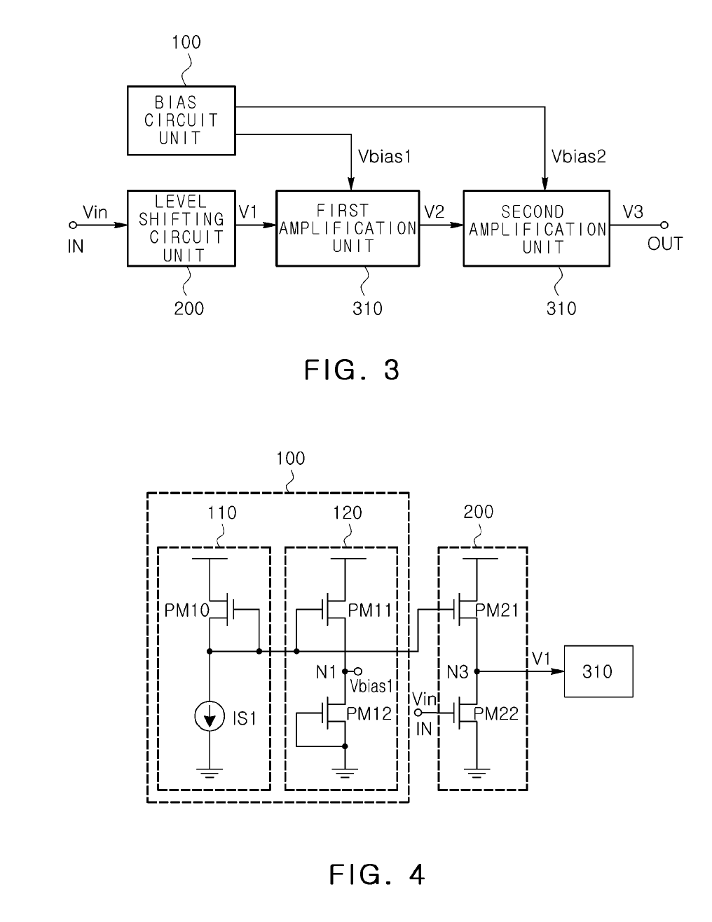

FIG. 3 is a block diagram of a small signal amplifier circuit according to another exemplary embodiment of the present disclosure.

Referring to FIG. 3, the small signal amplifier circuit according to this exemplary embodiment of the present disclosure may include a bias circuit unit 100, a level shifting circuit unit 200, a first amplification unit 310, and a second amplification unit 320.

The bias circuit unit 100 may generate a first bias voltage V_{bias1} and a second bias voltage V_{bias2} different from the first bias voltage V_{bias1} so as to provide the first amplification unit 310 and the second amplification 320, respectively.

The level shifting circuit unit 200 may shift an input AC signal Vin by an amount equal to a predetermined DC shifting voltage V_{shift} to provide a first signal V1.

The first bias voltage V_{bias1} and the DC shifting voltage V_{shift} may be generated in circuits having the identical characteristic, and, if so, the first bias voltage V_{bias1} and the DC shifting voltage V_{shift} may be almost the identical DC voltage.

The first amplification unit 310 may amplify a difference signal between the first bias voltage V_{bias1} and the first signal V1 to provide a second signal V2.

The second amplification unit 320 may amplify a difference signal between the second bias voltage V_{bias2} and the second signal V2 to provide a third signal V3.

Although the first amplification unit 310 may be used solely, the second amplification unit 320 may be additionally used if the obtained gain is insufficient.

FIG. 4 is a block diagram of a bias circuit unit and a level shifting circuit unit according to an exemplary embodiment of the present disclosure.

Referring to FIG. 4, the bias circuit unit 100 may include a current source circuit 110 generating electric currents, and a bias generation unit 120 forming a current mirror together with the current source circuit 110 such that generating the first bias voltage V_{bias1} based on the current generated by the current source circuit 110.

The current source circuit 110 may include a main PMOS transistor having a source terminal connected to a terminal of supply voltage VDD and gate and drain terminals connected to each other, a current source IS1 connected between the drain terminal of the main PMOS transistor PM10 and ground.

The current source IS1 generates a predetermined current, which flows from the terminal of supply voltage VDD to ground through the main PMOS transistor PM10.

The first bias generation unit 120 may include: the first PMOS transistor PM11 forming a current mirror together with the main PMOS transistor PM10 and a second PMOS transistor PM12 having a source terminal connected to the drain terminal of the first PMOS transistor PM11 and gate and drain terminals connected to ground.

Since the first PMOS transistor PM11 and the main PMOS transistor PM10 form the current mirror, if the main PMOS transistor PM10 and the first PMOS transistor PM11 have the same size, a current equal to one flowing through the main PMOS transistor PM10 flows through the first PMOS transistor PM11.

Further, at the connection node N1 between the first PMOS transistor PM11 and the second PMOS transistor PM12, the first bias voltage V_{bias1} may be provided.

The level shifting circuit unit 200 may include: the first PMOS transistor PM21 forming a current mirror together with the main PMOS transistor, and a second PMOS transistor PM22 having a source terminal connected to the drain terminal of the first PMOS transistor PM21, a gate terminal in which the input AC signal Vin is received, and a drain terminal connected to ground.

Since the first PMOS transistor PM21 in the level shifting circuit unit 200 and the main PMOS transistor PM10 form the current mirror, if the main PMOS transistor PM10 and the first PMOS transistor PM21 have the same size, a current equal to one flowing through the main PMOS transistor PM10 flows through the first PMOS transistor PM21 in the level shifting circuit unit 200.

At the connection node N3 between the first PMOS transistor PM21 and the second PMOS transistor PM22, the first signal V1 may be provided.

Further, the second PMOS transistor PM12 in the first bias generation unit 120 and the second PMOS transistor PM22 in the level shifting circuit unit 200 may have the same size and the same characteristic.

Further, the second PMOS transistor PM22 in the level shifting circuit unit 200 may receive the input AC signal Vin at its gate terminal and may amplify it by the drain-source voltage so as to output it at its drain terminal. The drain-source voltage may correspond to the DC shifting voltage V_{shift}.

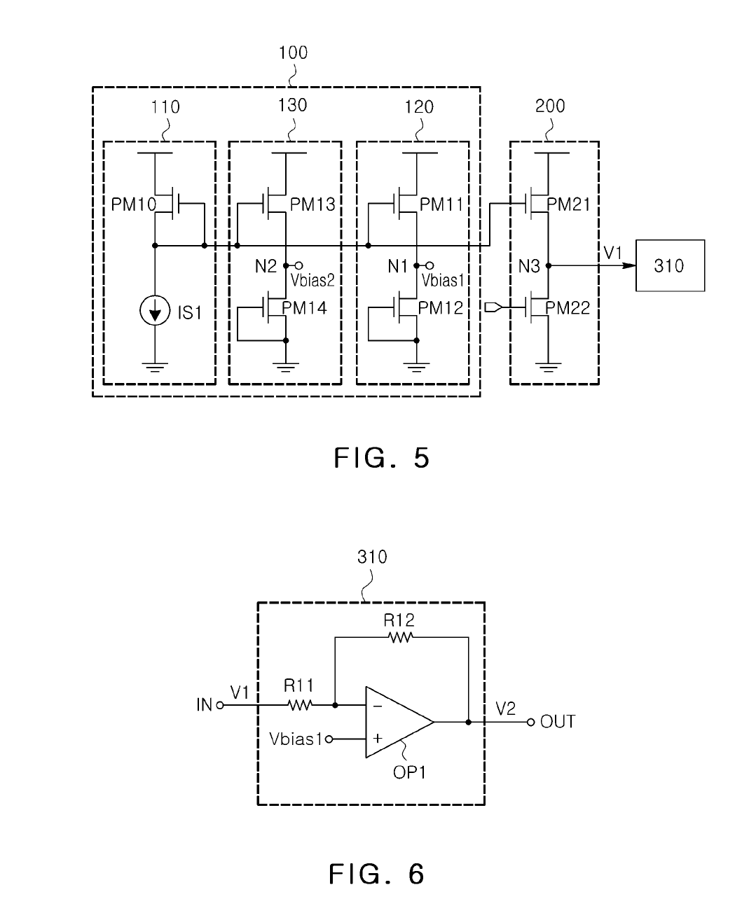

FIG. 5 is a block diagram of a bias circuit unit and a level shifting circuit unit according to another exemplary embodiment of the present disclosure.

Referring to FIG. 5, the bias circuit unit according to this exemplary embodiment of the present disclosure may include a current source circuit 110, a first bias generation unit 120, and a second bias generation unit 130.

The operations of the bias circuit unit 110 and the first bias generation unit 120 shown in FIG. 5 are identical to those described above with respect to FIG. 4 and, therefore, redundant descriptions will not be made.

The second bias generation unit 130 may form a current mirror together with the current source 110 and may generate a second bias voltage V_{bias2} based on the current generated by the current source circuit 110.

For example, the second bias generation unit 130 may include: a third PMOS transistor PM13 forming a current mirror together with the main PMOS transistor PM10, and a fourth PMOS PM14 having a source terminal connected to the drain terminal of the third PMOS transistor PM13 and gate and drain terminals connected to ground.

Since the third PMOS transistor PM13 and the main PMOS transistor PM10 form the current mirror, if the main PMOS transistor PM10 and the third PMOS transistor PM13 have the same size, a current equal to one flowing through the main PMOS transistor PM10 flows through the third PMOS transistor PM11.

Alternatively, if the main PMOS transistor PM10 and the third PMOS transistor PM13 have different sizes, a current that is different from the one flowing through the main PMOS transistor PM10 flows through the third PMOS transistor PM13.

Further, at the connection node N2 between the third PMOS transistor PM13 and the fourth PMOS transistor PM14, the second bias voltage V_{bias2} may be provided.

For example, if the main PMOS transistor PM10 and the third PMOS transistor PM13 have different sizes, a current that is different from the one flowing through the main PMOS transistor PM10 flows through the third PMOS transistor PM13. Accordingly, if the size of the main PMOS transistor PM10 is larger than that of the third PMOS transistor PM13, the second bias circuit unit 130 may generate the second bias voltage V_{bias2} that is higher than the first bias voltage V_{bias1}.

FIG. 6 is a diagram of a first amplification unit according to an exemplary embodiment of the present disclosure.

Referring to FIG. 6, the first amplification unit 310 may include a first operational amplifier OP1 having a non-inverting input terminal in which the first bias voltage V_{bias1} is received, an inverting terminal in which the first signal V1 is received via a first resistor R11, and an output terminal connected to the inverting input terminal via the second resistor R12.

The first operational amplifier OP1 may invert and amplify a difference signal obtained by subtracting the first bias voltage V_{bias1} from the first signal V1 by a gain determined according to the ratio of resistance between the first and second resistors R11 and R12.

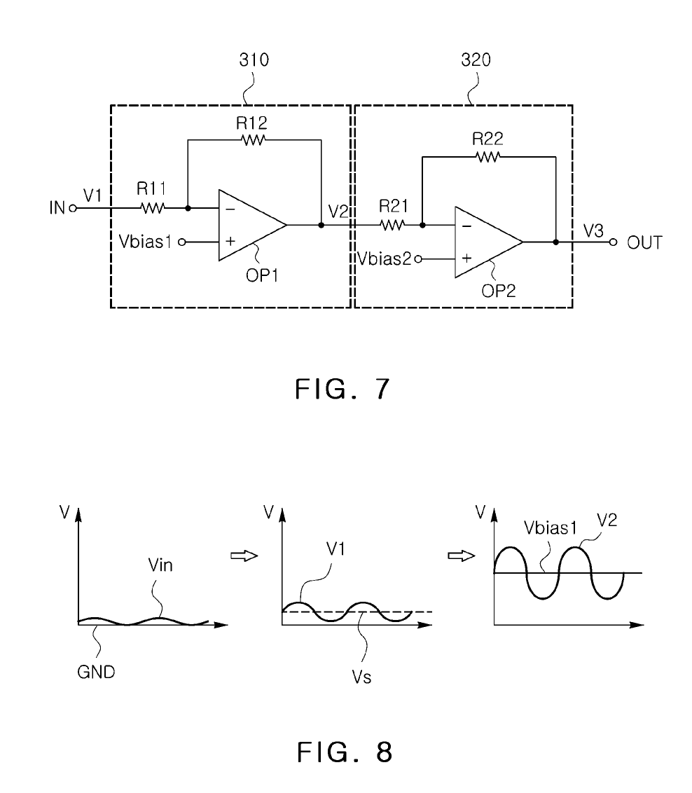

FIG. 7 is a diagram of a first amplification unit and a second amplification unit according to an exemplary embodiment of the present disclosure. The first amplification unit 310 shown in FIG. 7 is identical to that of FIG. 6 and thus will not be described again.

The second amplification unit 320 may include a second operational amplifier OP2 having an inverting input terminal in which the first bias V_{bias1} is received, a non-inverting terminal in which the second signal V2 is received via a third resistor R21, and an output terminal connected to the inverting input terminal via the fourth resistor R22.

The second operational amplifier OP2 may invert and amplify a difference signal obtained by subtracting the first bias voltage V_{bias1} from the second signal V2 by a gain determined according to the ratio of resistance between the third and fourth resistors R21 and R22.

As set forth above, according to exemplary embodiments, by employing a level shifting structure and a single amplification circuit, small and simple design with less power consumption can be achieved. Further stable amplification can be secured.

While exemplary embodiments have been shown and described above, it will be apparent to those skilled in the art that modifications and variations could be made without departing from the spirit and scope of the present disclosure as defined by the appended claims.

What is claimed is:

1. A signal amplifier circuit, comprising:
a bias circuit unit configured to generate a first bias voltage;
a level shifting circuit unit configured to shift a level of an input alternating current (AC) signal by an amount equal to a predetermined direct current (DC) shifting voltage so as to provide a first signal; and
a first amplification unit configured to amplify a difference signal between the first bias voltage and the first signal, the first bias voltage and the DC shifting voltage being generated by circuits having the same characteristics.

2. The signal amplifier circuit of claim 1, wherein the bias circuit unit comprises:
a current source circuit including a main PMOS transistor having a source terminal connected to a terminal of supply voltage and gate and drain terminals connected to each other, and a current source connected between the drain terminal of the main PMOS transistor and ground; and
a first bias generation unit including a first PMOS transistor forming a current mirror together with the main PMOS transistor, and a second PMOS transistor having a source terminal connected to the drain of the first PMOS transistor and gate and drain terminals connected to ground, wherein the first bias voltage is provided at a connection node between the first PMOS transistor and the second PMOS transistor.

3. The signal amplifier circuit of claim 1, wherein the level shifting circuit unit includes:
a first PMOS transistor forming a current mirror together with the bias circuit unit; and
a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

4. The signal amplifier circuit of claim 1, wherein the first amplification unit includes a first operational amplifier having a non-inverting input terminal in which the first bias voltage is received, an inverting input terminal in which the first signal is received via a first resistor, and an output terminal connected to the inverting input terminal via a second resistor, wherein the first operational amplifier inverts and amplifies a difference signal obtained by subtracting the first bias voltage from the first signal by a gain determined according to a ratio of resistance between the first and second resistors.

5. A signal amplifier circuit, comprising:
a bias circuit unit configured to generate a first bias voltage;
a level shifting circuit unit configured to shift a level of an input alternating current (AC) signal by an amount equal to a predetermined direct current (DC) shifting voltage so as to provide a first signal;
a first amplification unit configured to amplify a difference signal between the first bias voltage and the first signal so as to provide a second signal; and
a second amplification unit configured to amplify a difference signal between the first bias voltage and the second signal so as to provide a third signal, the first bias voltage and the DC shifting voltage being generated by circuits having the same characteristics.

6. The signal amplifier circuit of claim 5, wherein the bias circuit unit includes:
a current source circuit including a main PMOS transistor having a source terminal connected to a terminal of supply voltage and gate and drain terminals connected to each other, and a current source connected between the drain terminal of the main PMOS transistor and ground; and
a first bias generation unit including a first PMOS transistor forming a current mirror together with the main PMOS transistor, and a second PMOS transistor having a source terminal connected to the drain of the first PMOS transistor and gate and drain terminals connected to ground, wherein the first bias voltage is provided at a connection node between the first PMOS transistor and the second PMOS transistor.

7. The signal amplifier circuit of claim 5, wherein the level shifting circuit unit includes:
a first PMOS transistor forming a current mirror together with the bias circuit unit; and
a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

8. The signal amplifier circuit of claim 5, wherein the first amplification unit includes a first operational amplifier having a non-inverting input terminal in which the first bias voltage is received, an inverting input terminal in which the first signal is received via a first resistor, and an output terminal connected to the inverting input terminal via a second resistor,
wherein the first operational amplifier inverts and amplifies a difference signal obtained by subtracting the first bias voltage from the first signal by a gain determined according to a ratio of resistance between the first and second resistors so as to provide the second signal.

9. The signal amplifier circuit of claim 5, wherein the second amplification unit includes a second operational amplifier having a non-inverting input terminal in which the first bias voltage is received, an inverting input terminal in which the second signal is received via a third resistor, and an output terminal connected to the inverting input terminal via a fourth resistor,
wherein the second operational amplifier inverts and amplifies a difference signal obtained by subtracting the first bias voltage from the second signal by a gain determined according to a ratio of resistance between the third and fourth resistors.

10. A signal amplifier circuit, comprising:
a bias circuit unit configured to generate a first bias voltage and a second bias voltage different from the first bias voltage;
a level shifting circuit unit configured to shift a level of an input alternating current (AC) signal by an amount equal to a predetermined direct current (DC) shifting voltage so as to provide a first signal;
a first amplification unit configured to amplify a difference signal between the first bias voltage and the first signal so as to provide a second signal; and
a second amplification unit configured to amplify a difference signal between the second bias voltage and the second signal so as to provide a third signal, the first bias voltage and the DC shifting voltage being generated by circuits having the same characteristics.

11. The signal amplifier circuit of claim 10, wherein the bias circuit unit includes:
a current source circuit including a main PMOS transistor having a source terminal connected to a terminal of supply voltage and gate and drain terminals connected to each other, and a current source connected between the drain terminal of the main PMOS transistor and ground;
a first bias generation unit including a first PMOS transistor forming a current mirror together with the main PMOS transistor, and a second PMOS transistor having a source terminal connected to the drain of the first PMOS transistor and gate and drain terminals connected to ground, wherein the first bias generation unit provides the first bias voltage at a connection node between the first PMOS transistor and the second PMOS transistor; and
a second bias generation unit including a third PMOS transistor forming a current mirror together with the main PMOS transistor, and a fourth PMOS transistor having a source terminal connected to the drain of the third PMOS transistor and gate and drain terminals connected to ground, wherein the second bias generation unit provides the second bias voltage at a connection node between the third PMOS transistor and the fourth PMOS transistor.

12. The signal amplifier circuit of claim 10, wherein the level shifting circuit unit includes:
a first PMOS transistor forming a current mirror together with the bias circuit unit; and
a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

13. The signal amplifier circuit of claim 11, wherein the first amplification unit includes a first operational amplifier having a non-inverting input terminal in which the first bias voltage is received, an inverting input terminal in which the first signal is received via a first resistor, and an output terminal connected to the inverting input terminal via a second resistor,
wherein the first operational amplifier inverts and amplifies a difference signal obtained by subtracting the first bias voltage from the first signal by a gain determined according to a ratio of resistance between the first and second resistors so as to provide the second signal.

14. The signal amplifier circuit of claim 11, wherein the second amplification unit includes a second operational amplifier having a non-inverting input terminal in which the second bias voltage is received, an inverting input terminal in which the second signal is received via a third resistor, and an output terminal connected to the inverting input terminal via a fourth resistor,
wherein the second operational amplifier inverts and amplifies a difference signal obtained by subtracting the first bias voltage from the second signal by a gain determined according to a ratio of resistance between the third and fourth resistors.

15. A signal amplifier circuit, comprising:
a current source circuit configured to generate electric current;
a first bias circuit unit forming a current mirror together with the current source circuit so as to generate a first bias voltage according to the electric current generated by the current source circuit;
a second bias circuit unit forming a current mirror together with the current source circuit so as to generate a second bias voltage according to the electric current generated by the current source circuit, the second bias voltage being higher than the first bias voltage;
a level shifting circuit unit configured to shift a level of an input AC signal by an amount equal to a predetermined DC shifting voltage so as to provide a first signal;
a first amplification unit configured to amplify a difference signal between the first bias voltage and the first signal so as to provide a second signal; and
a second amplification unit configured to amplify a difference signal between the second bias voltage and the second signal so as to provide a third signal, the first bias voltage and the DC shifting voltage being generated by transistor circuits having the same characteristics.

16. The signal amplifier circuit of claim 15, wherein the current source circuit includes:
a main PMOS transistor having a source terminal connected to a terminal of supply voltage and gate and drain terminals connected to each other; and
a current source connected between the drain terminal of the main PMOS transistor and ground.

17. The signal amplifier circuit of claim 15, wherein a first bias generation unit includes:
a first PMOS transistor forming a current mirror together with the main PMOS transistor, and a second PMOS transistor having a source terminal connected to the drain of the first PMOS transistor and gate and drain terminals connected to ground, wherein the first bias voltage is provided at a connection node between the first PMOS transistor and the second PMOS transistor.

18. The signal amplifier circuit of claim 15, wherein a second bias generation unit includes:
a third PMOS transistor forming a current mirror together with the main PMOS transistor; and
a fourth PMOS transistor having a source terminal connected to the drain of the third PMOS transistor and gate and drain terminals connected to ground, wherein the second bias voltage is provided at a connection node between the third PMOS transistor and the fourth PMOS transistor.

19. The signal amplifier circuit of claim 15, wherein the level shifting circuit unit includes:
a first PMOS transistor forming a current mirror together with the bias circuit unit; and
a second PMOS transistor having a source terminal connected to a drain terminal of the first PMOS transistor, a gate terminal in which the input AC signal is received and a drain terminal connected to ground, wherein the first signal is provided at a connection node between the first PMOS transistor and the second PMOS transistor.

20. The signal amplifier circuit of claim 15, wherein the first amplification unit includes a first operational amplifier having a non-inverting input terminal in which the first bias voltage is received, an inverting input terminal in which the first signal is received via a first resistor, and an output terminal connected to the inverting input terminal via a second resistor, wherein the first operational amplifier inverts and amplifies a difference signal obtained by subtracting the first bias voltage from the first signal by a gain determined according to a ratio of resistance between the first and second resistors so as to provide the second signal, and
the second amplification unit includes a second operational amplifier having a non-inverting input terminal in which the second bias voltage is received, an inverting input terminal in which the second signal is received via a third resistor, and an output terminal connected to the inverting input terminal via a fourth resistor, wherein the second operational amplifier inverts and amplifies a difference signal obtained by subtracting the first bias voltage from the second signal by a gain determined according to a ratio of resistance between the third and fourth resistors.
